(19) United States
(12) Patent Application Publication
(10) Pub. No.: US 2003/0030494 A1
(43) Pub. Date: Feb. 13, 2003

(54) Low noise balanced amplifier

(76) Inventor: Guanghua Huang, Prior Lake, MN (US)

Correspondence Address: MERCHANT & GOULD PC, P.O. BOX 2903, MINNEAPOLIS, MN, 55402-0903, US

(21) Appl. No.: 10/145,403

(22) Filed: May 13, 2002

Related U.S. Application Data
(63) Continuation-in-part of application No. 09/759,968, filed on Jan. 13, 2001.

(51) Int. Cl. H03F 3/191

(52) U.S. Cl. 330/302

(57) ABSTRACT

In the first circuit arrangement, a low noise balanced microwave amplifier includes an input coupler having an integrated noise-matching circuit, a single-ended amplifier in each branches, and an output coupler. The impedance at each output port of the input coupler is set close or equal to the optimum noise source impedance of an active gain device in the single-ended. No additional circuit element or only one shunt inductor or capacitor is needed for the noise matching. The total insertion loss of the input network is reduced to improve the overall noise figure. In the second circuit arrangement, two low noise amplifiers of microwave monolithic integrated circuit (MMIC) are used for the active gain device within the balanced amplifier. The MMIC are matched close to or equal to the optimum noise source impedance at the input of the MMIC and to the optimum intermodulation impedance at the output rather than the nominal characteristic impedance of the MMIC such as 50-Ohm to improve the noise figure and intermodulation performance.

### REFERENCE TO CO-PENDING APPLICATIONS

The present application is a continuation in part of U.S. patent application Ser. No. 09/759,968 filed on Jan. 13, 2001 and entitled Low Noise Balanced Microwave Amplifier.

### TECHNICAL FIELD

The present invention discloses low noise balanced microwave amplifiers and more particularly with balanced amplifiers having an input coupler as part of the noise-matching network and with balanced amplifiers.

### BACKGROUND

It is presently known to use a low noise balanced amplifier (LNBA) comprising an input 3-dB-90° coupler, two identical low noise single-ended amplifier (LNSA) in each branch, and an output 3-dB-90° coupler. Typically, each LNSA is connected to each output port of the input coupler with the output port impedance to be the nominal value, which is 50-Ohm. Each LNSA comprises in series an input noise matching network, an active gain device, and an output-matching network. The input noise-matching network converts the nominal source impedance of 50 Ohm to the pre-determined optimum noise source impedance for the active gain device.

Comparing to a single-ended low noise amplifier, a low noise balanced amplifier offers following advantages: 1) to obtain the minimum noise performance and the good return loss at the same time at the input; 2) to have better stability; 3) to have improved output radio frequency (RF) power level; 4) to have better intermodulation performance; and 5) to have redundancy. However, besides higher cost, a LNBA, generally offers higher noise figure than a LNSA because of the insertion loss of the input 3-dB-90° coupler. For example, a typical 0.20 to 0.40 dB insertion loss is observed for an input 3-dB-90° coupler at 1.90 GHz PCS frequency. The total noise figure of 0.70 to 0.90 dB is, taking into account the 0.2˜0.4 dB insertion loss of the input coupler, resulted for a PCS LNBA if the active gain device such as a transistor has a typical noise figure of 0.30 dB and the input noise-matching network has an insertion loss of 0.20 dB.

A LNBA is widely used in telecommunications such as in a cellular phone base station because of the advantages mentioned above. However, lower noise figure is the key that determines the receiving sensitivity of the system. This is especially important to a cellular phone base station. A base station having lower noise figure provides wider coverage, increasing the battery life of a handset, and reducing the RF radiation exposure to a handset user.

It is presently known that the transmitting power of a handset is limited mainly by the battery capacity and the physical size. Higher sensitivity of the base station can receive weaker signal transmitted from a handset and thus coverage will be increased.

It is presently known that a base station sends a control signal to reduce the transmitting power of a handset if the base station detects the stronger signal (better signal-to-noise ratio) when the handset user is close to the base station. The transmitting power of a handset can be further reduced because of the higher sensitivity of the base station. Then, longer battery life and lower RF transmitting power are resulted.

It is presently known that the typical noise figure of a best LNBA is in the range of 0.70 dB to 1.0 dB up to 5 GHz frequency band at room temperature. 0.50 dB or lower noise figure of a LNBA is highly desired.

It is presently known that low noise monolithic microwave integrated circuit (MMIC) amplifiers have been widely used, especially in higher frequency bands. A low noise MMIC has the advantage of the small size with the drop-in simplicity in applications because the input and output ports of the MMIC are matched to the nominal impedance such as 50-Ohm. In other words, the design of the input and output matching networks are not needed using a low noise MMIC amplifier. However, a low noise MMIC amplifier trades off its noise performance for the input matching performance.

It is presently known that low noise MMIC amplifiers have emerged in the frequency 10 GHz or above, well extended into millimeter wave bands. These low noise MMIC amplifiers, using integrated GaAs technology, offer miniature size with drop-in feature. However, the noise figure is in the range of 2.0 dB to 4.0 dB from 20 GHz to 40 GHz frequency range.

A low noise figure amplifier having a noise figure in 1.0 dB or below is desired in 20 GHz to 40 GHz ranges.

### SUMMARY

One aspect of the present invention is a balanced amplifier having an integrated coupler and impedance matching scheme. Impedance has a resistive component and a reactive component. The balanced amplifier comprises first and second active gain devices. Each of the first and second active gain devices has a noise source impedance. A coupler has an input port, a first output port in electrical communication with the first active gain device, and a second output port in electrical communication with the second active gain device. The coupler has a first transmission line arrangement between the input port and the first output port, and a second transmission line arrangement between the input port and the second output port. The physical structure of the first and second transmission line arrangements matches at least one impedance component of the noise source impedance of the first and second active gain devices, respectively, without an impedance matching network being positioned between the coupler and the first and second active gain devices.

Another aspect of the present invention is a method of amplifying an electrical signal. The method comprises inputting an electrical signal into a coupler; conducting the signal along a first transmission line arrangement to a first output port, the first transmission line having an impedance; conducting the signal along a second transmission line arrangement to a second output port, the second transmission line having an impedance; passing the signal directly from the first output port to a first active gain device, the impedance of the first output port substantially matching the noise source impedance of the first active gain device; and passing the signal directly from the second output port to a second active gain device, the impedance of the second output port substantially matching the noise source impedance of the second active gain device.

### BRIEF DESCRIPTION OF THE DRAWINGS

FIG. 1 is a schematic diagram of a balanced amplifier according to the prior art.

FIG. 2 is a schematic diagram of each of two identical single-ended amplifiers contained within the balanced amplifier of FIG. 1.

FIG. 3 is a schematic diagram of a 3-dB-90° Wilkinson coupler utilized within an input portion of the balanced amplifier of FIG. 1.

FIG. 4 is a schematic diagram of a 3-dB-90° Wilkinson coupler utilized within an output portion of the balanced amplifier of FIG. 1.

FIG. 5 is a schematic diagram of an impedance matching network used with the single ended amplifier of FIG. 2.

FIG. 6 is a graph illustrating the optimum noise source impedance and noise circles of a single-ended amplifier or a transistor as a function of frequency.

FIG. 7 is a graph illustrating the classical noise matching impedance contour.

FIG. 8 is a schematic diagram illustrating a Wilkinson coupler embodying the present invention.

FIG. 9 is a graph illustrating the noise matching impedance contour of a coupler embodying the present invention.

FIG. 10 is a schematic diagram illustrating a quadrature coupler embodying the present invention.

FIG. 11 is a schematic diagram illustrating a Lange coupler embodying the present invention.

FIG. 12 is a schematic diagram illustrating a parallel-coupled line coupler embodying the present invention.

### DETAILED DESCRIPTION

Various embodiments of the present invention, including a preferred embodiment, will be described in detail with reference to the drawings wherein like reference numerals represent like parts and assemblies throughout the several views. Reference to the described embodiments does not limit the scope of the invention, which is limited only by the scope of the appended claims.

In general terms, the present invention relates to a low noise balanced amplifier configuration in which the mechanism for noise matching at the input of amplifiers is to integrate the noise source impedance matching network into the input coupler. In this configuration, the noise source impedance matching mechanism introduces less insertion loss between the input of the amplifier and the active gain device to improve the overall noise figure of the amplifier. Impedance is expressed as Z=R+jX, where Z is the impedance, R is the real or resistive component of the impedance, and X is the imaginary or reactive component of impedance.

The present invention also generally relates to the noise matching method of a balanced amplifier that comprises a low noise MMIC amplifier within each signal branch. In this configuration, the noise source impedance of the output ports of the input coupler is selected close to the optimum noise source impedance of the MMIC to reduce the noise figure of the LNBA instead of merely using a nominal impedance such as 50 Ohms. Also in this configuration, the load impedance of the MMIC is chosen for the best intermodulation performance instead of the nominal impedance such as 50 Ohms.

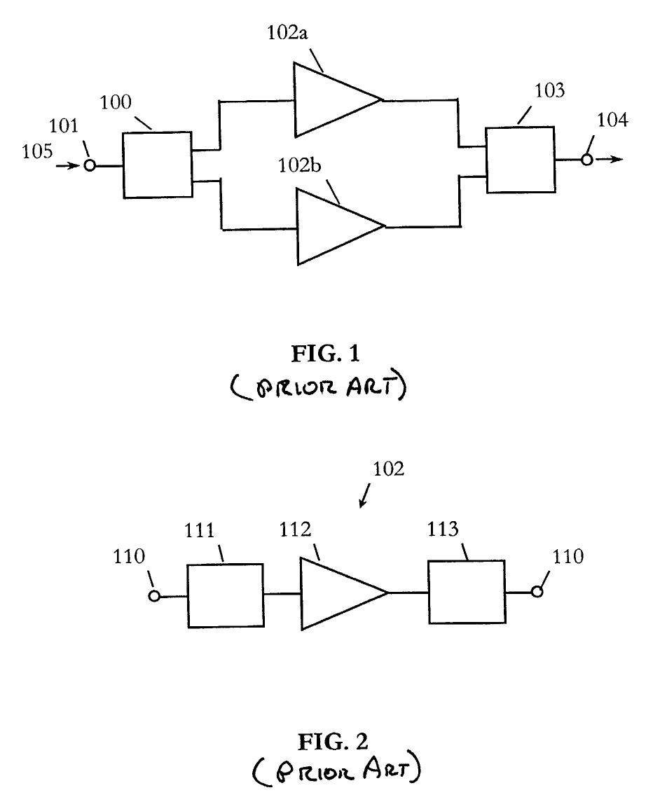

Before describing the present invention, it will be helpful to review the design of a conventional microwave balanced amplifier and the disadvantage inherent in it. FIG. 1 illustrates a low noise microwave balanced amplifier in accordance with the prior art. An input microwave signal 105 is applied to an input port 101, which signal travels to an input coupler 100, which in one possible embodiment is a 3-dB-90° coupler. A portion of the input signal passes through the coupler 100 to a one single-ended amplifier 102a, and another portion of the input signal passes through-the coupler 100 and is coupled to another single-ended amplifier 102b. The outputs of the single-ended amplifiers 102a and 102b are transmitted to an output coupler 103, which in one possible embodiment is a 3-dB-90° coupler. The output coupler 103 combines the amplified signals and transmits the combined signal to the output port 104.

FIG. 2 illustrates the circuit diagrams within each of the single-ended amplifiers 102a and 102b. Each of the amplifiers 102 includes an input matching network 111, an active gain device 112, and an output-matching network 113. The input matching network 111 converts the output impedance of the coupler, which is typically 50 Ohms, to the required noise source impedance for the active gain device 112.

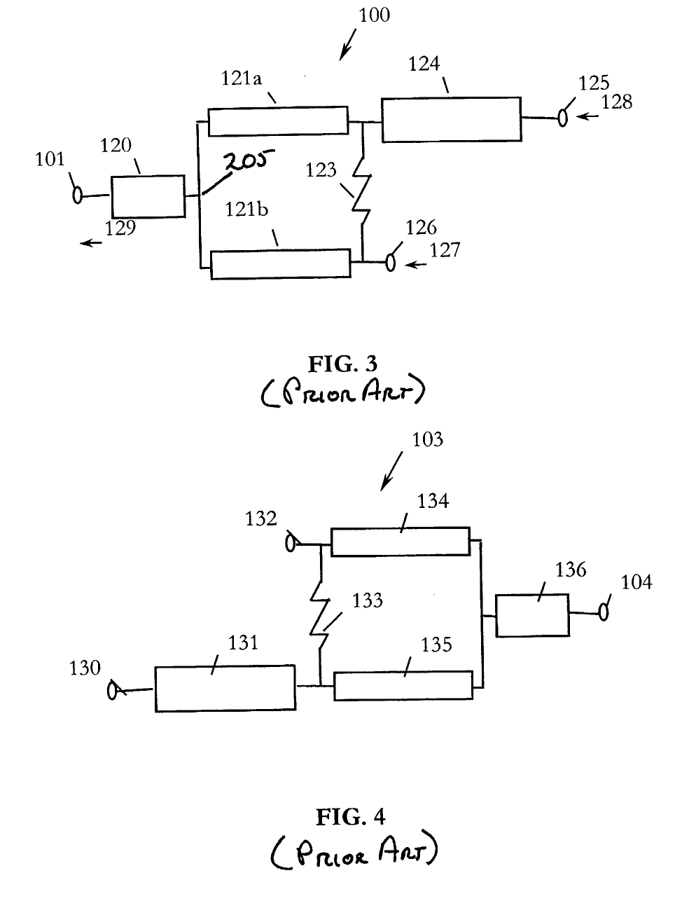

FIG. 3 schematically illustrates the coupler 100 in the input portion of the balanced amplifier, and FIG. 4 schematically illustrates the coupler 103 in the output portion of the balanced amplifier. As illustrated, in one possible embodiment the input coupler 100 and the output coupler 103 are Wilkinson 90° couplers.

Referring to FIG. 3, one possible embodiment of the Wilkinson coupler 100 has an input port 101 that sees a source impedance 129, a first output port 126 with an output impedance of 127, and a second output port 125 with an output impedance 128. A signal path 120 extends between the input port and a node 205. Identical quarter wavelength transmission lines 121a and 121b, whose characteristic impedance is \sqrt{2} times the nominal impedances at the input port 101 and output ports 125 and 126 of the coupler 100, have a first end that are connected to the node 205. A resistor 123 with the resistance of 2 times the nominal impedance of the output port 125 or 126, such as a 100-Ohm resistor, is connected between the second, opposite ends of each transmission line 121. An additional quarter wavelength element 124 with the characteristic impedance of 50 Ohms extends between the second end of the transmission line 121a and the output port 125. The additional quarter wavelength element 124 is a 90° phase shifter. The second end of the quarter wavelength transmission line 121b communicates directly to an output port 126. The two output ports 125 and 126 of the coupler have an output impedance such as 50 Ohms.

FIG. 5 illustrates one type of structure that- typically has been used to form the impedance matching network 111 between the coupler 100 and the active gain device 112. The impedance matching network 111 is formed with a high-impedance transmission line that has an input node 110 at a first end and an output node 206 at a second end. The input node 110 is connected in series to either the quarter wavelength transmission line 124 at output port 125 or the quarter wavelength transmission line 121b at output port 127 depending on the branch of the balanced amplifier to which the impedance matching network 111 is connected. The output node 206 is connected to the input of the active gain device 112. The second end of the high impedance transmission line is shunted to ground 163 through an inductor 162. The impedance matching network, looking into the output node 206, has an impedance 164.

FIG. 6 is a Z-impedance Smith Chart 140 illustrating the optimum noise source impedance of a hypothetical, but typical, active gain device such as a GaAs FET transistor. The dashed-line 141 is the optimum noise source impedance as it varies with frequency. The counter clockwise direction along 141 indicates the frequency increase direction. For example, the point 144 is the optimum noise impedance at 880 MHz, and the point 145 is the optimum noise impedance at 12,000 MHz. Circles 143 and 142 are equal noise circles relating to the noise source impedances required for the active gain device to produce 0.25 dB and 0.50 dB, respectively, which are higher noise figures than the optimum noise figure. It is desirable to select the noise source impedance close to or equal to the optimum noise impedance of the active gain device 112. In FIG. 5, for exemplary purposes only, the noise source impedance that is close to or equal the optimum noise impedance is hypothetically set at point 144 at a given frequency.

FIG. 7 graphically illustrates one noise matching impedance contour of the classical method. The source impedance 129, as shown in FIG. 3, is the nominal impedance Z₀ that is labeled as 150 on the Smith Chart 140′. The output impedances 127 and 128, as shown in FIG. 3, are located on the point 150 since 127 and 128 are equal to the nominal impedance Z₀. A certain insertion loss, however, is introduced because of the loss of the signal paths of 120, 121, and 124. The high impedance transmission line 161, shown in FIG. 5, transforms resistive component of the source impedance at the point 150 to the point 154 in FIG. 7. Then, the shunt inductor 162, or alternatively a shunt high impedance transmission line, is used to transform the reactive component of the impedance at the point 154 to the final predetermined noise source impedance at the point 151, which is close to the optimum noise source impedance at the point 144 for the active gain device. Using the impedance matching network 111 introduces another insertion loss into the balanced amplifier because of loss in the signal paths of 161 and 162. The total insertion losses from signal paths of the input coupler 100 and the impedance matching network 111 are directly added to the noise figure of the LNBA.

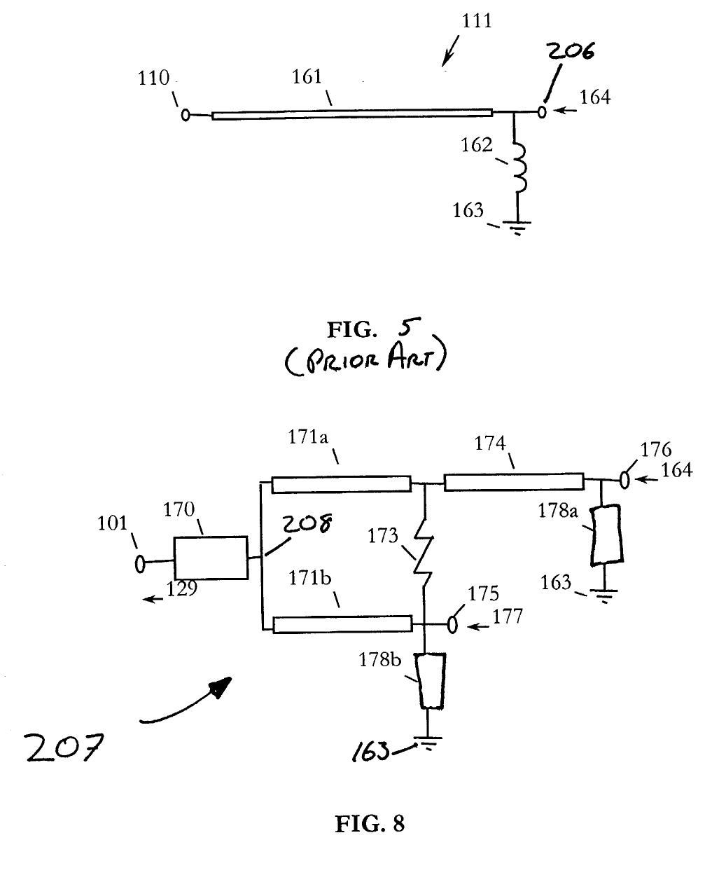

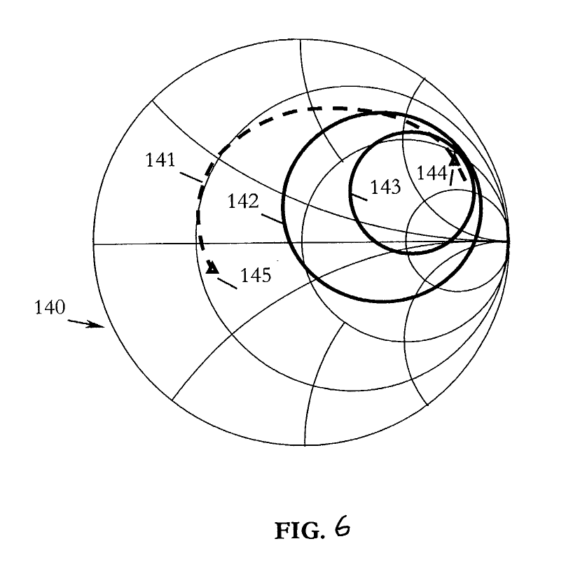

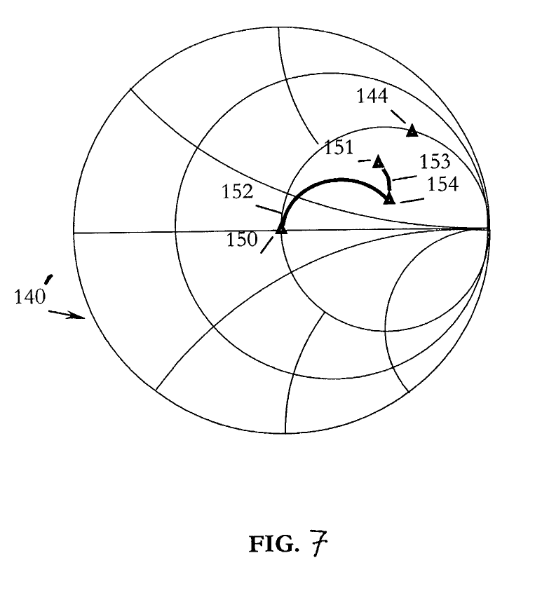

FIG. 8 illustrates an integrated input coupler and the noise-matching network 207 that embodies the present invention. In the illustrated embodiment, the integrated input coupler and noise-matching network 207 is a Wilkinson coupler.

The integrated input coupler and noise-matching network 207 has an input port 101 that sees a source impedance 129, a first output port 175 with an output impedance of 177, and a second output port 176 with an output impedance 164. A signal path 170 extends between the input port and a node 208. Quarter wavelength transmission lines 171a and 171b have a first end that are connected to the node 208. A resistor 173 is connected between the second, opposite ends of each transmission line 171. An additional quarter wavelength element 174 is a 90° phase shifter and extends between the second end of the transmission line 171a and the output port 176. The additional quarter wavelength element 174 is a 90° phase shifter. The second end of the quarter wavelength transmission line 171b communicates directly to the output port 175. In one possible embodiment, the resistive component of the output impedance 164 is in the range from about 10 Ohms to about 500 Ohms.

The transmission lines can be formed with any type of electrical conductor that can be used to form a coupler. One example includes microstrips or other traces mounted on a substrate. In one possible embodiment, the substrate can be a material having dielectric properties and a grounding plane on the backside. Another example of a conductor is a coaxial cable, which has an inner conductor along its axis, a core that may have dielectric properties surrounding the conductor, a shield surrounding the core, and a jacket.

In one possible embodiment, the physical structure of the integrated input coupler and the noise-matching network 207 is modified to tune the impedance of the integrated input coupler and the noise-matching network 207 to match the input noise source impedance requirement of the active gain device 112. The physical structure of the integrated input coupler and noise-matching network 207 can be changed in several different ways. One possible way to change the structure is to change the length, width, and thickness of the quarter wavelength transmission lines (or other conductors) 171 and 174. Changing the physical dimensions of the quarter wavelength transmission lines 171 and 174, will change both the resistive (i.e., real) and possibly the reactive (i.e., imaginary) components of the output impedance 164 or 177.

Alternatively, the thickness or dielectric coefficient of the substrate on which the quarter wavelength transmission lines 171 and 174 are mounted can be changed. Changing the structure of the substrate changes the reactance of the transmission line, which in turn changes the reactive component of the impedance. In this embodiment, the quarter wavelength transmission lines 171a and 171b may not have identical structures, because their structure may be adjusted to alter their impedance. Similarly, if the transmission line is a coaxial cable, the thickness and dielectric properties of the core can be changed.

As illustrated in FIG. 8, if modifying the structure of the integrated input coupler and the noise-matching network 207 does not adequately modify the reactive component of the impedance, a reactive component 178a and 178b can be arranged within the coupler to shunt to ground 163 the second or output end of the quarter wavelength transmission lines 174 and 171b, respectively. In one possible embodiment, the reactive components 178 are inductors if the desired reactance or imaginary component of the noise source impedance has a positive value and are capacitors if the desired reactance component of the noise source impedance has a negative value.

Different amplifiers used within the balanced amplifier can have different noise performance characteristics. For example, some amplifiers require only the resistive component of the noise source impedance, while other amplifiers require both the resistive and reactive components of the noise source impedance. As a result, different physical characteristics of the input coupler can be set to tune the resistive (real) and/or reactive (imaginary) components of the noise source impedance to match the corresponding resistive and/or reactive components, respectively, of the amplifier.

If only the resistive component of impedance needs to be matched, then the couple does not need to include the reactive components 178. If it is desired to match the reactive component of the impedance the coupler circuit can includes the reactive components 178, if the transmission lines themselves do not provide the desired reactance. The reactive components 178 are inductors if the desired reactive component of the impedance is greater than zero (0<jX). The reactive components 178 are capacitors if the desired reactive component of the impedance is less than zero (0>jX).

Within the structure illustrated in FIG. 8 and described herein, the quarter wavelength transmission line 174 that functions as a 90° phase shifter has the predetermined characteristic impedance Z₀ₛ instead of Z₀. The resistor 173 has the resistance value of 2 Z₀ₛ. The characteristic impedance Z₀₁ of quarter wavelength transmission lines 171 is determined by \sqrt{2Z₀Z₀ₛ}.

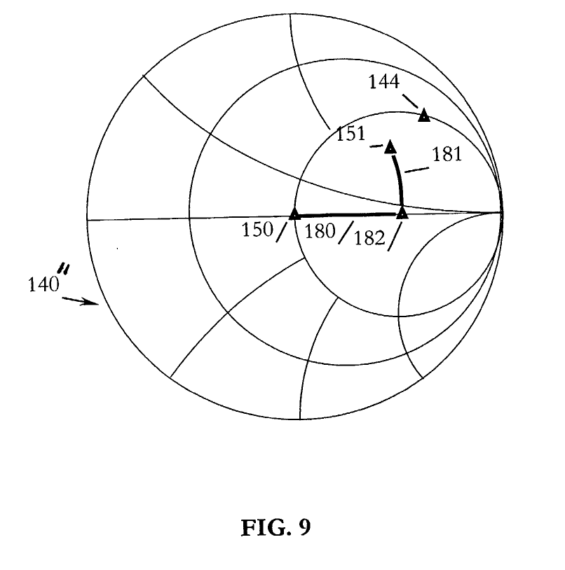

FIG. 9 illustrates the impedance matching contour of the integrated input coupler and noise-matching network 207 and the active gain device 112. The source impedance 129, as shown in FIG. 8, is the nominal impedance Z₀ and is labeled as 150 on the Smith Chart 140″. The output impedances 177 and 164 without the reactive components 178, as shown in FIG. 8, are directly transformed to the point 182. Because the desired reactance component of the impedance has a positive value, shunt inductors, or alternatively a high impedance transmission lines, are used for the reactive components 178. The reactive components 178 form a shunt inductor to ground 163 and transform the impedance at 182 to the final predetermined noise source impedance at the point 151, which is close to the optimum noise source impedance at the point 144 for the active gain device 112. Only the insertion loss of the integrated input coupler and impedance matching network 207 is introduced. The insertion loss that results from a separate impedance matching network is eliminated which improves the total noise figure of the balanced amplifier. For example, a 0.50 dB noise figure is obtained instead of a 0.70 dB noise figure at the PCS frequency band. Another advantages of the invention disclosed herein is that it enables balanced amplifiers having improved gain, noise figure, and return loss figures over a wider bandwidth. Yet another advantage is that eliminating a separate impedance matching network reduces the total number of circuit components and thus reduces the cost of the amplifier.

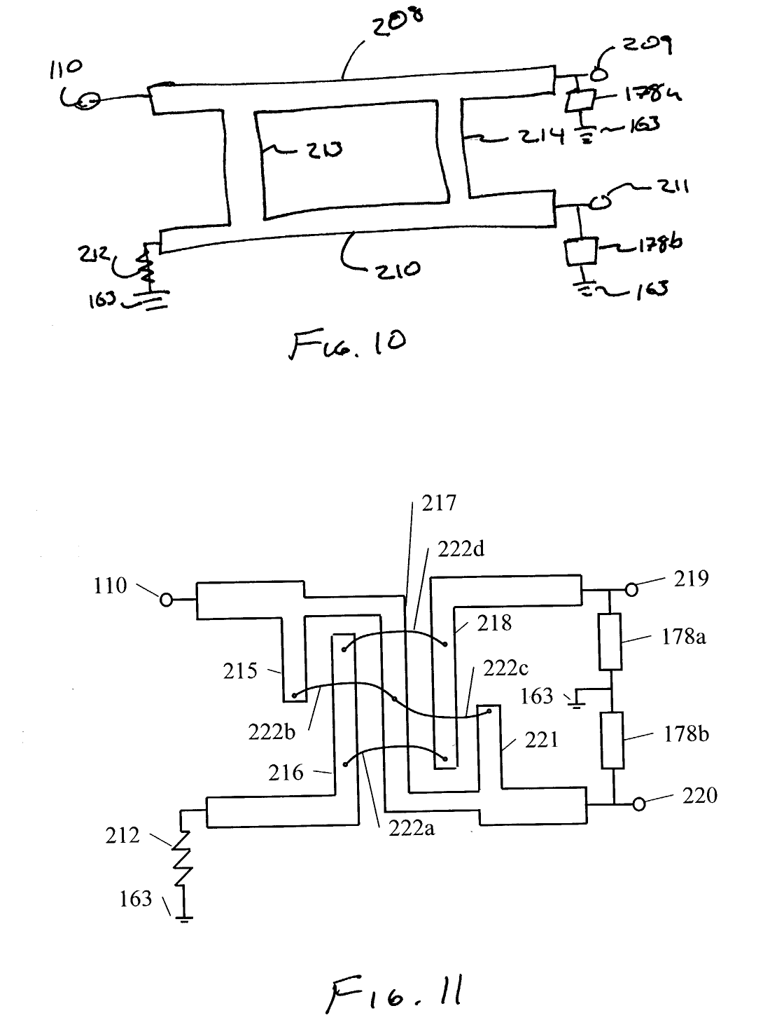

Although a Wilkinson couple is described above, other types of couplers can embody the invention as well. Referring to FIG. 10, for example, one alternative embodiment integrates the impedance-matching network and a 3-dB-90° quadrature coupler. In this embodiment, a first transmission line 208 runs from an input port 110 to a first output port 209. A second transmission line 210 runs to a second output port 211. A resistor 212 is between the second transmission line 210 and ground 163. Two quarter-wavelength transmission lines 213 and 214 extend between the first and second transmission lines 208 and 210. In this embodiment, the physical structure of the quadrature coupler is adjusted to modify the output impedance at both the first and second output ports to be Z₀ₛ and match the required noise source impedance of the active gain device 112.

The physical structure of the quadrature coupler can be adjusted by changing the dimensions of the transmission lines 208, 210, 213, and 214, the thickness of the substrate on which the transmission lines 208, 210, 213, and 214 are mounted, and/or the dielectric constant of the substrate material, and/or any other physical change that alters the impedance to the desired value. If the reactive component sill needs to be adjusted after they physical parameters are adjusted match the resistive component of the impedance, reactive devices 178a and 178b can be arranged within the quadrature coupler and shunted between ground 163 and the first and second outputs 209 and 211, respectively.

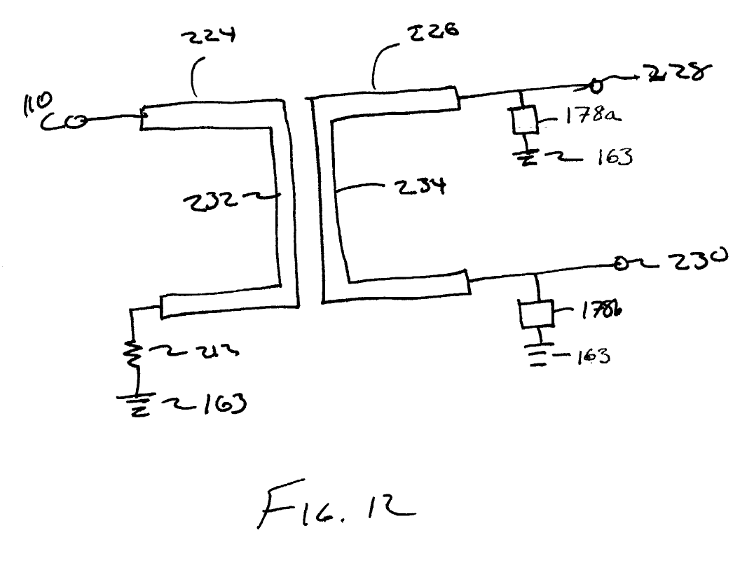

Yet another possible embodiment integrates the noise impedance-matching network into the Lange coupler as illustrated in FIG. 11. In this embodiment, first, second, third, fourth, and fifth transmission lines 215, 216, 217, 218, and 221 run parallel to each other. Both the first and third transmission lines 215 and 217 have a first end connected to an input port 110. The second end of the third transmission line 217 and first end of the fifth transmission line 221 are connected to the output port 220. The second end of the first transmission line 215 is connected to the center of the third transmission line 217 through the jumper 222b. The center of the third transmission line 217 is then connected to the second end of the fifth transmission line 221 through the jumper 222c. The first end of the second transmission line 216 is connected to the first end of the fourth transmission line 218 through the jumper 222a, and the second end of the second transmission line 216 is connected to the second end of the fourth transmission line 218 through the jumper 222d. The second end of the fourth transmission line 218 is connected to the output port 219.

In this embodiment, the physical structure of the Lange coupler is adjusted to modify the output impedance at both the first and second output ports to be Z₀ₛ and match the required input noise source impedance of the active gain device 112. The physical structure can be adjusted by changing the dimensions of the transmission lines 215, 216, 217, 218, and 221, the thickness of the substrate on which the transmission lines 215, 216, 217, 218, and 221 are mounted, and/or the dielectric constant of the substrate material, and/or any other physical change that alters the impedance to the desired value such as the spaces between the transmission lines 215, 216, 217, 218, and 221. If the reactive component sill needs to be adjusted after they physical parameters are adjusted to match the resistive component of the noise source impedance, reactive devices 178a and 178b can be shunted between ground 163 and the first and second output ports 219 and 220, respectively.

Referring to FIG. 12, yet another possible embodiment integrates the impedance-matching network and a parallel-coupled line coupler. In this embodiment, a first transmission line 224 is u-shaped transmission line has a first end connected to an input port 110 and a second end connected to ground 163 through a resistor 212. A second transmission line 226 is u-shaped and has a first end connected to a first output port 228 and a second end connected to a second output port 230. A central section 232 of the first transmission line 224 extends parallel to a central section 234 of the second transmission line 226 so that there is coupling between 232 and 234 sections .

In this embodiment, the physical structure of the parallel-coupled line coupler is adjusted to modify the output impedance at both the first and second output ports to be Z₀ₛ and match the required noise source input impedance of the active gain device 112. The physical structure can be adjusted by changing the dimensions and space of the transmission lines 232 and 234, the thickness of the substrate on which the transmission lines 232 and 234 are mounted, and/or the dielectric constant of the substrate material, and/or any other physical change that alters the impedance to the desired value. If the reactive component sill needs to be adjusted after they physical parameters are adjusted match the resistive component of the impedance, reactive devices 178a and 178b can be shunted between ground 163 and the first and second ends of the second transmission line 226, respectively.

The claimed invention is:

1. A balanced amplifier having an integrated coupler and impedance matching scheme, the impedance having a resistive component and a reactive component, the balanced amplifier comprising:
first and second active gain devices, each of the first and second active gain devices having a noise source impedance;
a coupler having an input port, a first output port in electrical communication with the first active gain device, and a second output port in electrical communication with the second active gain device, the coupler having a first transmission line arrangement between the input port and the first output port, and a second transmission line arrangement between the input port and the second output port; and
wherein the physical structure of the first and second transmission line arrangements matches at least one impedance component of the noise source impedance of the first and second active gain devices, respectively, without an impedance matching network being positioned between the coupler and the first and second active gain devices.

2. The balanced amplifier of claim 1 wherein:
the first transmission line arrangement includes at least one transmission line forming a first signal path, the at least one transmission line having dimensions providing of the first signal path with a resistive component of the impedance that substantially matches the resistive component of the noise source impedance for the first active gain device; and
the second transmission line arrangement includes at least one transmission line forming a second signal path, the at least one transmission line having dimensions providing of the second signal path with a resistive component of the impedance that substantially matches the resistive component of the noise source impedance for the second active gain device.

3. The balanced amplifier of claim 2 wherein the first transmission line arrangement path has an output end connected to the first output port and the second transmission line arrangement has an output end connected to the second output port, the balanced amplifier further comprising:
a first reactive component shunting the output end of the first transmission line arrangement to ground; and
a second reactive component shunting the output end of the second transmission line arrangement to ground.

4. The balanced amplifier of claim 3 wherein the reactive component is selected from the group consisting essentially of: an inductor and a capacitor.

5. The balanced amplifier of claim 1 wherein the first and second transmission line arrangements are mounted on a substrate, the physical structure of the substrate providing the first and second transmission line arrangements with an impedance that substantially matches the noise source impedance of the first and second active gain devices, respectively.

6. The balanced amplifier of claim 1 wherein the coupler is of the type selected from the group consisting essentially of: a Wilkinson coupler, a quadrature coupler, a parallel-coupled line coupler, and a Lange coupler.

7. The balanced amplifier of claim 1 wherein the first and second transmission line arrangements are formed with coaxial cables, each coaxial cable having a predetermined characteristics impedance.

8. The balanced amplifier of claim 1 wherein the first and second transmission line arrangements are formed with microstrips.

9. The balanced amplifier of claim 1 wherein the active gain devices are formed with one or more transistors.

10. The balanced amplifier of claim wherein the active gain devices are formed with monolithic microwave integrated circuits.

11. A method of amplifying an electrical signal, the method comprising:
inputting an electrical signal into a coupler;
conducting the signal along a first transmission line arrangement to a first output port, the first transmission line having an impedance;
conducting the signal along a second transmission line arrangement to a second output port, the second transmission line having an impedance;
passing the signal directly from the first output port to a first active gain device, the impedance of the first output port substantially matching the noise source impedance of the first active gain device; and
passing the signal directly from the second output port to a second active gain device, the impedance of the second output port substantially matching the noise source impedance of the second active gain device.

12. The method of claim 11 further comprising:
shunting the first transmission line to ground with a reactive component; and
shunting the second transmission line to ground with a reactive component.

13. The method of claim 12 wherein:
conducting the signal along the first transmission line includes transmitting the signal along a microstrip, the microstrip having dimensions to provide a resistive component of the first output port impedance substantially matching the resistive component of the noise source impedance for the first active gain device; and
conducting the signal along the second transmission line includes transmitting the signal along a microstrip, the microstrip having dimensions to provide a resistive component of the second output port impedance substantially matching the resistive component of the noise source impedance for the second active gain device.

14. The method of claim 12 wherein:
conducting the signal along the first transmission line includes transmitting the signal along a coaxial cable having a conductor, the conductor having dimensions to provide a resistive component of the first output port impedance substantially matching the resistive component of the noise source impedance for the first active gain device; and
conducting the signal along the second transmission line includes transmitting the signal along a coaxial cable having a conductor, the conductor having dimensions to provide a resistive component of the second output port impedance substantially matching the resistive component of the the second active gain device

15. The method of claim 12 wherein:
passing the signal directly from the first output port to a first active gain device includes passing the signal to a transistor; and
passing the signal directly from the second output port to a second active gain device includes passing the signal to a transistor.

16. The method of claim 12 wherein:
passing the signal directly from the first output port to a first active gain device includes passing the signal to a monolithic microwave integrated circuit; and
passing the signal directly from the second output port to a second active gain device includes passing the signal to a monolithic microwave integrated circuit.
